(19) United States
(12) Patent Application Publication
(10) Pub. No.: US 2007/0195975 A1
(43) Pub. Date: Aug. 23, 2007

(54) Meters for dynamics processing of audio signals

(76) Inventors: Davis S. Cotton, Albany, CA (US); Ian E. Esten, San Francisco, CA (US); Todd J. Hodges, Millbrac, CA (US); Bobby Lombardi, San Francisco, CA (US); Joseph P. Saracino, San Francisco, CA (US); James R. West, Oakland, CA (US); David G. Willenbrink, San Francisco, CA (US)

Correspondence Address: PETER J. GORDON, PATENT COUNSEL, AVID TECHNOLOGY, INC., ONE PARK WEST, TEWKSBURY, MA, 01876, US

(21) Appl. No.: 11/175,629

(22) Filed: Jul. 6, 2005

(51) Int. Cl. H03G 3/00; H03G 9/00

(52) U.S. Cl. 381/104; 381/102; 715/727

(57) ABSTRACT

A gain reduction meter for dynamics processing provides information describing which part of a dynamics curve is affecting the input signal. In particular, the gain reduction meter displays an amount of gain reduction due to applying a dynamics processing operation in a manner that differentiates between gain reduction achieved by the different parts of the dynamics curve for that dynamics processing operation. The gain reduction meter has a plurality of display elements. Each display element corresponds to an amount of gain reduction. The illumination of the display elements is controlled such that the appearance of each illuminated display element is dependent on where on the dynamics curve the amount of gain reduction corresponding to that display element is produced.

### BACKGROUND

A common form of processing of audio signals is called dynamics processing, which is any processing that alters the dynamics of an audio signal. Examples of dynamics processing include, but are not limited to, compression, limiting, expansion, gating and de-essing. Compression involves reducing the difference between highest and lowest level of the sound, primarily by reducing higher level signals. Expansion involves expanding the difference between the highest and lowest levels of the sound by reducing the volume of the lower level parts of a signal. Both compression and expansion can be described by a function curve, called a dynamics curve, that maps output levels to input levels. Limiting involves clipping a signal when it goes above a certain level. Gating involves cutting a signal when it falls below a certain level. A de-esser is a type of compressor that is sensitive to sounds with high frequencies, such as the sound produced by the letter “s.”

Audio hardware and software have one or more gain reduction meters. These meters display to an operator an indication of any change in the audio signal caused by dynamics processing. In general a gain reduction meter displays an amount of gain reduction, typically measured in decibels. Many audio mixers have gain reduction meters that are a linear array of monochromatic light emitting diodes (LEDs) with associated labels that indicate an amount of gain reduction measured in decibels. As the amount of gain reduction increases, more of the light emitting diodes are illuminated, up to the LED that is associated with a label corresponding to the amount of gain reduction produced by the dynamics processing operation. Alternatively, some audio mixers display a two-dimensional graph that displays the dynamics curve and a position of the input signal on that curve—an indirect indication of gain reduction. However, such a two-dimensional graph is too large for most mixers. Gain reduction meters also may be simulated in a computer display.

### SUMMARY

Dynamics processing (and its associated dynamics curve) affects the level of the output signal depending on the input signal level. Dynamics processing also often affects the timbre (tonal character) of the output signal depending on the input signal level. A gain reduction meter would be more useful if it were able to help an operator answer several questions simultaneously. One of these questions is how much gain reduction, in decibels is occurring. Another question is what (coarsely) is the slope of the dynamics curve that is now being engaged (which relates to how rapidly is the output level changing as a function of the input level). Yet another question is how much the dynamics processing is affecting the signal timbre.

A gain reduction meter can provide this information by displaying the amount of gain reduction caused by dynamics processing in a manner that differentiates between gain reduction achieved by the different parts of the dynamics curve for that dynamics processing operation. In particular, a gain reduction meter has a plurality of display elements. Each display element corresponds to an amount of gain reduction. The illumination of the display elements is controlled such that the appearance of each illuminated display element is dependent on where on the dynamics curve the amount of gain reduction corresponding to that display element is produced.

In general, as the amount of gain reduction increases, more of the display elements are illuminated, up to the display element corresponding to an amount of gain reduction produced by the dynamics processing operation. The display elements may be implemented, for example but not limited to, by one or more picture elements (pixels) in a display or by a set of multicolor light emitting diodes. Some of the display elements may be associated with labels indicating the corresponding amount of gain reduction. A characteristic of an illuminated display element is dependent on where on the dynamics curve the amount of gain reduction corresponding to that display element is produced. For example, different display elements corresponding to gain reduction on different parts of the dynamics curve may be displayed with different colors.

For example, for compression/limiting, the gain reduction meter differentiates between when gain reduction occurs in the knee and when gain reduction reaches full compression. Such differentiation may be provided by using a first characteristic for display elements corresponding to gain reduction in the knee and a second characteristic, different from the first characteristic, for display elements corresponding to gain reduction representing full compression.

As another example, for expansion/gating, the gain reduction meter differentiates between when gain reduction is performed in the middle segment of the expansion curve and when gain reduction is applied past the threshold. Such differentiation may be provided by using a first characteristic for display elements corresponding to gain reduction in the middle segment of the expansion curve and a second characteristic for display elements corresponding to gain reduction past the threshold.

### BRIEF DESCRIPTION OF THE DRAWINGS

FIG. 1 is an example user interface for a compressor.

FIG. 2 is an example user interface for an expander.

FIG. 3 is an example vertical linear meter for showing gain reduction.

FIG. 4 is an example arc-shaped meter for showing gain reduction.

### DETAILED DESCRIPTION

Common dynamics processing operations include, but are not limited to, compression, limiting, expansion, gating and de-essing. These processing operations can be implemented using analog circuits, digital circuits, computer software, or combinations thereof. These operations can be performed using a standalone audio mixer or console, or in a computer program executed on a computer, or in a combination of a control surface with a computer that performs audio processing.

Each dynamics processing operation typically has an associated gain reduction meter that communicates to an operator the amount of gain reduction, for example measured in decibels, due to applying the dynamics processing operation. Gain reduction meters may reside in the mixer, console or control surface, or may be displayed on a computer display or other display device associated with the mixer, console or control surface.

To provide additional information to the operator about which part of a dynamics curve is affecting the input signal, the gain reduction meter differentiates between gain reduction achieved by different parts of the dynamics curve for that dynamics processing operation. In particular, the gain reduction meter communicates information about the amount of gain reduction and the slope of the dynamics curve. The illumination of the display elements in the gain reduction meter is controlled such that the appearance of each illuminated display element is dependent on where on the dynamics curve the amount of gain reduction corresponding to that display element is produced

An explanation of some types of dynamics processing operations, and user interfaces for defining parameters for such operations will first be described. Implementations of example gain reduction meters will then be described.

Compression reduces the dynamic range of signals that exceed a chosen threshold by a specific amount. A “threshold” control sets the level of the signal at which compression is triggered. Signals that exceed this level are compressed. Signals that are below it are generally unaffected. A threshold setting of 0 dB is equivalent to no compression. An “attack” control sets a response time, or attack, after which the compressor reduces the gain applied to the signal. A “release” control sets the amount of time that it takes for the gain to return to its original level after the signal falls below the threshold. To use compression most effectively, the attack time should be set so that signals exceed the threshold level long enough to cause an increase in the average level. An appropriate attack setting helps ensure that gain reduction does not decrease the overall volume. Release times should be set long enough so that if signal levels repeatedly rise above the threshold, they cause gain reduction to be triggered only once. If the release time is too long, a loud section of the audio material could cause gain reduction that persists through a soft section. Of course, compression has many creative uses that break these general guidelines.

Limiting, which is similar to heavy compression, prevents signal peaks from ever exceeding a chosen threshold, and is generally used to prevent short-term peaks from reaching their full amplitude. Used judiciously, limiting produces higher average levels, while avoiding overload (clipping or distortion), by limiting only some short-term transients in the source audio. To prevent the ear from hearing the gain changes, extremely short attack times (such as 1 millisecond) and release times are used. Limiting is used to remove only occasional peaks because gain reduction on successive peaks would be noticeable. If audio material contains many peaks, the threshold should be raised and the gain manually reduced so that only occasional, extreme peaks are limited. Most limiters have ratios of 10:1 or 20:1, although some provide ratios of up to 100:1. Large ratios effectively limit the dynamic range of the signal to a specific value by setting an absolute ceiling for the dynamic range. Limiting can be useful for hard-limiting the dynamic range for broadcast or band-limited media.

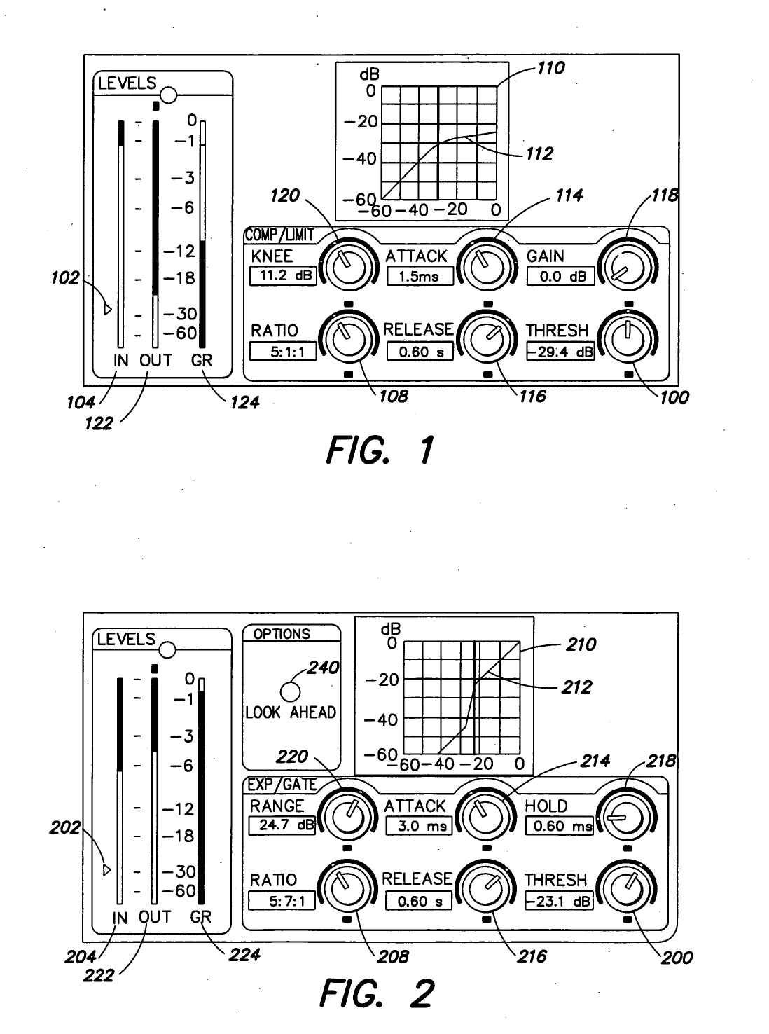

A graphical user interface for a computer program implementation of a compressor/limiter is shown in FIG. 1.

In FIG. 1, a threshold control 100 sets the threshold level. An operator may manipulate the graphical knob to adjust the threshold setting or type in a value using a keyboard. An arrow 102 on an input level meter 104 (which shows peak signal levels before dynamics processing) indicates the current threshold. The arrow 102 also can be configured to allow an operator to drag it up or down to adjust the threshold setting. A dynamics graph display 110 also can show the threshold as a vertical line 112. This line 112 also can be configured to allow an operator to drag it left or right to adjust the threshold setting. An output level meter 122 shows the level of the output signal after any gain reduction. A gain reduction meter 124 shows the amount of gain reduction, in decibels, that is caused by the dynamics processing.

A ratio control 108 sets a compression ratio, which is the amount of compression applied as the input signal exceeds the threshold. An operator may manipulate the graphical knob to adjust the ratio or type in a value using a keyboard. For example, a 2:1 compression ratio means that a 2 dB increase of level above the threshold produces a 1 dB increase in output above the threshold level. As the ratio control is adjusted, the dynamics graph display 110 is updated to illustrate how the shape of the compression curve changes.

An attack control 114 sets the attack time, which is the rate at which gain is reduced after the input signal crosses the threshold. An operator may manipulate the graphical knob to adjust the attack or type in a value using a keyboard. The smaller the value, the faster the attack. The faster the attack, the more rapidly the compressor/limiter applies attenuation to the signal.

A release control 116 sets the length of time it takes for the Compressor/Limiter to be fully deactivated after the input signal drops below the threshold. An operator may manipulate the graphical knob to adjust the release or type in a value using a keyboard.

A gain control 118 boosts or reduces overall output gain to compensate for heavily compressed or limited signals. An operator may manipulate the graphical knob to adjust the gain or type in a value using a keyboard.

Finally, a knee control 120 sets a rate at which the compressor reaches full compression after the threshold has been exceeded. An operator may manipulate the graphical knob to adjust the knee or type in a value using a keyboard. As the knee control is adjusted, the dynamics graph display 110 is updated to illustrate how the shape of the expansion curve changes.

Using such controls, compression and limiting are defined by a function, called a dynamics curve, that has three stages: a first stage represents a 1:1 compression slope before a threshold, a second stage around the threshold called the “knee”, and a third stage with a steeper slope that is the specified compression ratio. The general shape of this curve can be displayed to the operator through the dynamics graph display 110.

Having now described compression and limiting, expansion and gating will now be described in connection with FIG. 2.

Expansion decreases the gain of signals that fall below a chosen threshold. It is particularly useful for reducing noise or signal leakage that creeps into recorded material as its level falls, as often occurs in the case of headphone leakage. Gating silences signals that fall below a chosen threshold. To enable gating, the ratio of the expander is set to its maximum value while using short attack, decay, and release settings. Expanders can be thought of as soft noise gates since they provide a gentler way of reducing noisy low-level signals than the typically abrupt cutoff of a gate.

A graphical user interface for a software implementation of an expander/gate is shown in FIG. 2.

In FIG. 2, a “threshold” control 200 sets the threshold level. An operator may manipulate the graphical knob to adjust the threshold setting or type in a value using a keyboard. An arrow 202 on an input level meter 204 (which shows peak signal levels before dynamics processing) indicates the current threshold. The arrow 202 also can be configured to allow an operator to drag it up or down to adjust the threshold setting. A dynamics graph display 210 also can show the threshold as a vertical line 212. This line 212 also can be configured to allow an operator to drag it left or right to adjust the threshold setting. In one embodiment, this control may have an approximate range of −60 dB to 0 dB (where 0 dB is equivalent to no expansion or gating). A default value for the threshold control, such as −30 dB, may be provided. An output level meter 222 shows the level of the output signal after any gain reduction. A gain reduction meter 224 shows the amount of gain reduction, in decibels, that is caused by the dynamics processing.

A ratio control 208 sets the amount of expansion. For example, a 2:1 expansion ratio means that all signals below the threshold are lowered by twice the difference between the signal level and the threshold. At a higher ratio (such as 30:1 or 40:1) the expander/gate functions like a gate by cutting off signals that fall below the threshold. An operator may manipulate the graphical knob to adjust the ratio, or may type in a value using a keyboard. As the ratio control is adjusted, the dynamics graph display 210 is updated to illustrate how the shape of the expansion curve changes.

An attack control 214 sets the attack time, which is the rate at which gain is reduced after the input signal crosses the threshold. An operator may manipulate the graphical knob to adjust the attack or type in a value using a keyboard. The attack is used along with the ratio setting to control the softness of the Expander's gain reduction curve.

A hold control 218 specifies the duration during which the expander/gate will stay in effect after the initial attack occurs. The hold time can be used as a function to keep the expander/gate in effect for longer periods of time with a single crossing of the threshold. It can also be used to prevent gate chatter that may occur if varying input levels near the threshold cause the gate to close and open very rapidly. An operator may manipulate the graphical knob to adjust the hold time or type in a value using a keyboard.

A release control 216 sets the length of time it takes for the Expander/Gate to close after the input signal falls below the threshold level and the hold time has passed. An operator may manipulate the graphical knob to adjust the release or type in a value using a keyboard.

A range control 220 sets the depth of the expander/gate when closed. In one embodiment, it may have a maximum low depth, such as −80 dB. Setting the gate to a higher range allows more and more of the gated audio that falls below the threshold to peek through the gate at all times. An operator may manipulate the graphical knob to adjust the range or type in a value using a keyboard.

Normally, dynamics processing begins when the level of the input signal crosses the threshold. When the “look ahead” button 240 is enabled, dynamics processing begins a short time, e.g., 8 milliseconds, before the level of the input signal crosses the threshold. Such a look ahead control is useful for avoiding the loss of transients that may have been otherwise cut off or trimmed in a signal.

It also should be noted that some compressors and expanders permit gain reduction to be triggered by a first signal, but then applied to a second signal. Such a compressor is said to have a sidechain input. The gain reduction meters in this case would indicate the amount of gain reduction on the second signal. A de-esser is commonly implemented using compressor with a sidechain input.

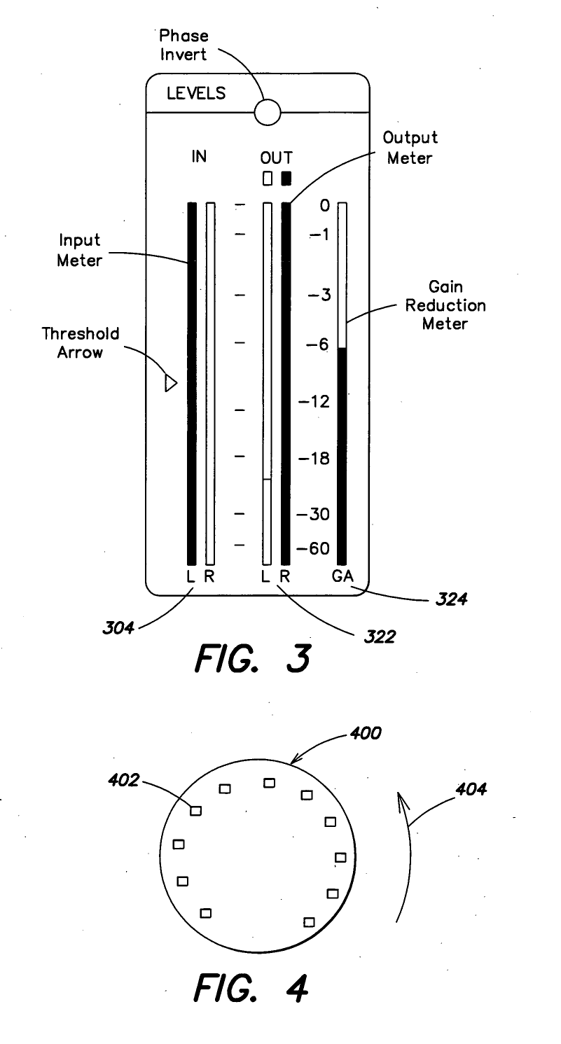

Referring now to FIG. 3, there are typically three meters associated with a compressor/limiter: input level meter 304, output level meter 322 and gain reduction meter 324. As noted above, the input level meter 304 shows the level of the input signal before any gain reduction. The output level meter 322 shows the level of the output signal after any gain reduction. The gain reduction meter 324 shows the amount of gain reduction, in decibels, that is caused by the dynamics processing. Gain reduction meters conventionally show increasing gain reduction by a descending vertical meter, whereas level meters show increasing levels by an ascending vertical meter. Horizontal meters sometimes are used, with increasing levels shown going left to right and increasing gain reduction shown going right to left. An arc-shaped meter, shown in FIG. 4 below, is another example configuration. The same input level, output level and gain reduction meters may be used for both compression/limiting operations and expansion/gating operations.

The gain reduction meter displays an amount of gain reduction due to applying a dynamics processing operation in a manner that differentiates between gain reduction achieved by the different parts of the dynamics curve for that dynamics processing operation. In particular, a gain reduction meter has a plurality of display elements. Each display element corresponds to an amount of gain reduction. The illumination of the display elements is controlled such that the appearance of each illuminated display element is dependent on where on the dynamics curve the amount of gain reduction corresponding to that display element is produced.

In general, as the amount of gain reduction increases, more of the display elements are illuminated, up to the display element corresponding to the amount of gain reduction produced by the dynamics processing operation. The display elements may be implemented, for example but not limited to, by one or more picture elements (pixels) in a display or by a set of multicolor light emitting diodes. Some of the display elements may be associated with labels indicating the corresponding amount of gain reduction. The meter may appear to be continuous, as shown in FIG. 3, or may appear as a set of discrete display elements as shown in FIG. 4 below. A characteristic of an illuminated display element id depending on where on the dynamics curve the amount of gain reduction corresponding to that display element is produced. For example, different display elements corresponding to gain reduction on different parts of the dynamics curve may be displayed with different colors.

For example, for compression/limiting, the gain reduction meter differentiates between when gain reduction occurs in the knee and when gain reduction reaches full compression. Such differentiation may be provided by using a first characteristic for display elements corresponding to gain reduction in the knee and a second characteristic, different from the first characteristic, for display elements corresponding to gain reduction representing full compression. The first and second characteristics may be, for example, different colors. The parameters used to define the dynamics curve provide the information used to determine whether an amount of gain reduction corresponds to the knee or full compression.

As another example, for expansion/gating, the gain reduction meter differentiates between when gain reduction is performed in the middle segment of the expansion curve and when gain reduction is applied past the threshold. Such differentiation may be provided by using a first characteristic for display elements corresponding to gain reduction in the middle segment of the expansion curve and a second characteristic, different from the first characteristic, for display elements corresponding to gain reduction past the threshold. The first and second characteristics may be, for example, different colors. The parameters used to define the dynamics curve provide the information used to determine whether an amount of gain reduction is either within the middle segment or past the threshold.

FIG. 4 illustrates an arc-shaped gain reduction meter 400. Increasing gain reduction is shown by illumination of the display elements 402 of the meter in a counter-clockwise direction. In particular, as gain reduction increases, more of the display elements of the meter are illuminated, in a counter-clockwise direction as indicated by arrow 404. The meter of FIG. 4 is illustrated as a set of discrete light emitting elements or a simulated display thereof. Such an arc-shaped display also may implemented to appear continuous. The display elements may be implemented in the same manner as for meters with display elements in a linear arrangement.

The dynamics processing and corresponding gain reduction meters such as described herein may be implemented in software or hardware, whether analog or digital, or firmware, or a combination thereof. The various elements of the system, either individually or in combination may be implemented as one or more computer program products in which computer program instructions are stored on a computer readable medium for execution by a computer. These operations can be performed using a standalone audio mixer or console, or in a computer program executed on a computer, or in a combination of a control surface with a computer that performs audio processing. The meters and control devices for dynamics processing may reside in a control surface which is in communication with a computer that performs the dynamics processing and communicates setting for the meters to the control surface.

If the dynamics processing and corresponding gain reduction meters are implemented as a computer program using a general-purpose computer system, such a computer system typically includes a main unit connected to both an output device that displays information to a user and an input device that receives input from a user. The main unit generally includes a processor connected to a memory system via an interconnection mechanism. The input device and output device also are connected to the processor and memory system via the interconnection mechanism.

One or more output devices may be connected to the computer system. Example output devices include, but are not limited to, a cathode ray tube (CRT) display, liquid crystal displays (LCD) and other video output devices, printers, communication devices such as a modem, and storage devices such as disk or tape. One or more input devices may be connected to the computer system. Example input devices include, but are not limited to, a keyboard, keypad, track ball, mouse, pen and tablet, communication device, control surface with various encoders, faders and other control devices, or other data input devices. The invention is not limited to the particular input or output devices used in combination with the computer system or to those described herein.

The computer system may be a general purpose computer system which is programmable using a computer programming language, a scripting language or even assembly language. The computer system may also be specially programmed, special purpose hardware. In a general-purpose computer system, the processor is typically a commercially available processor. The general-purpose computer also typically has an operating system, which controls the execution of other computer programs and provides scheduling, debugging, input/output control, accounting, compilation, storage assignment, data management and memory management, and communication control and related services.

A memory system typically includes a computer readable medium. The medium may be volatile or nonvolatile, writeable or nonwriteable, and/or rewriteable or not rewriteable. A memory system stores data typically in binary form. Such data may define an application program to be executed by the microprocessor, or information stored on the disk to be processed by the application program. The invention is not limited to a particular memory system.

Having now described an example embodiment, it should be apparent to those skilled in the art that the foregoing is merely illustrative and not limiting, having been presented by way of example only. Numerous modifications and other embodiments are within the scope of one of ordinary skill in the art and are contemplated as falling within the scope of the invention.

What is claimed is:

1. A meter for representing gain reduction due to dynamics processing on an input audio signal, wherein the dynamics processing is represented by a dynamics curve that maps an input signal to an amount of gain reduction, comprising:
a plurality of display elements, wherein each display element corresponds to an amount of gain reduction, and
means for controlling illumination of the plurality of display elements according to an amount of gain reduction due to the dynamics processing on the input audio signal, wherein an appearance of each illuminated display element is dependent upon where on the dynamics curve the amount of gain reduction corresponding to the display element is produced.

2. The meter of claim 1, wherein the means for controlling illumination of the plurality of display elements includes means for illuminating each display element corresponding to an amount of gain reduction up to the amount of gain reduction due to the dynamics processing on the input audio signal.

3. The meter of claim 1, wherein the dynamics processing is compression, and the dynamics curve has a knee and a threshold, and wherein display elements corresponding to gain reduction in the knee are displayed with a first characteristic and wherein display elements corresponding to gain reduction at full compression are displayed with a second characteristic different from the first characteristic.

4. The meter of claim 3, wherein the first characteristic is a first color and the second characteristic is a second color.

5. The meter of claim 1, wherein the dynamics processing is expansion, and the dynamics curve has a middle segment and a threshold, and wherein display elements corresponding to gain reduction in the middle segment are displayed with a first characteristic and wherein display elements corresponding to gain reduction past the threshold are displayed with a second characteristic different from first characteristic.

6. The meter of claim 5, wherein the first characteristic is a first color and the second characteristic is a second color.

7. The meter of claim 1, wherein each of the plurality of display elements has an associated label that indicates the corresponding amount of gain reduction

8. The meter of claim 1, wherein each display element is a light emitting diode.

9. The meter of claim 1, wherein each display element is one or more pixels on a display.

10. The meter of claim 1, wherein the display elements are arranged linearly.

11. The meter of claim 1, wherein the display elements are arranged in an arc.

12. An audio console, comprising:
a plurality of dynamics processing elements that apply gain reduction to an input signal, wherein the dynamics processing is represented by a dynamics curve that maps an input signal to an amount of gain reduction;
wherein each of the dynamics processing elements includes a meter, and wherein each meter comprises:
a plurality of display elements, wherein each display element corresponds to an amount of gain reduction, and
means for controlling illumination of the plurality of display elements according to an amount of gain reduction due to the dynamics processing on the input audio signal, wherein an appearance of each illuminated display element is dependent upon where on the dynamics curve the input audio signal is located.

13. The audio console of claim 12, wherein each of the plurality of display elements is a multicolor light emitting diode.

14. A computer system for processing audio data, comprising:
a plurality of dynamics processing elements that apply gain reduction to an input signal, wherein the dynamics processing is represented by a dynamics curve that maps an input signal to an amount of gain reduction;
wherein each of the dynamics processing elements includes a meter, and wherein each meter comprises:
a plurality of display elements, wherein each display element corresponds to an amount of gain reduction, and
means for controlling illumination of the plurality of display elements according to an amount of gain reduction due to the dynamics processing on the input audio signal, wherein an appearance of each illuminated display element is dependent upon where on the dynamics curve the input audio signal is located.

15. The computer system of claim 14, wherein the plurality of display elements includes pixels on a computer display.
